(19) United States
(12) Patent Application Publication
(10) Pub. No.: US 2009/0213563 A1
(43) Pub. Date: Aug. 27, 2009

(54) Interconnecting device and method used to electrically mount a daughter board to a motherboard

(75) Inventors: De-Jin Chen, ShenZhen (CN); Yu-San Hsiao, Tu-Cheng (TW); Meng-Xia Shang, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 12/380,089

(22) Filed: Feb. 23, 2009

(30) Foreign Application Priority Data
Feb. 22, 2008 (CN) 200810018541.1

(51) Int. Cl. H05K 1/14; H01R 12/00

(52) U.S. Cl. 361/803; 439/65; 439/67

(57) ABSTRACT

A device for connecting printed circuit boards. The device comprises an insulative housing and a plurality of conductive terminals arranged in the insulative housing. The insulative housing defines a first mounting surface, a second mounting surface, and flat pickup portions respectively disposed on opposite faces of the first mounting face and the second mounting face; each terminal includes a first leg on the first mounting surface, and a second leg on the second mounting surface.

### BACKGROUND OF THE INVENTION

1. Field of the invention

The present invention relates to an interconnecting device, and more particularly to an interconnecting device mounted to a daughter board so as to electrically assembling the daughter board to a motherboard.

2. Background of the Invention

Usually, it is required to connect two printed circuit boards in an electronic device. So how to establish expediently a steady electrical connection between the two printed circuit boards is one of the most common concerns in the technical art.

U.S. Pat. No. 5,836,780 issued to Mizumura on Nov. 17, 1998 (hereinafter referred to as Mizumura's '780 patent) discloses an electrical connector for connecting two printed circuit boards. With reference to Figs. in Mizumura's '780 patent, the electrical connector 100 is electrically mounted onto a first printed circuit board 400, and a second printed circuit board 200 is inserted into a receiving cavity of the electrical connector 100 by hand. The first printed circuit board 400 and the second printed circuit board 200 are fixed via the electrical connector 100, and an electrical connection therebetween is established via the electrical connector 100. When it is required to cut the electrical communication between the first and the second printed circuit boards 400, 200, the second printed circuit board 200 can be pulled out of the receiving cavity of the electrical connector 100 by hand. Thus, the second printed circuit board 200 can be changed easily. However, the connection manner needs to be operated manually, comparing automatic operation, it is not a cost-effective way to manufacture.

### SUMMARY OF THE INVENTION

It is an object of the present invention is to provide a device and a method for connecting two printed circuit boards which can easily realize an automatic operation and improve manufacturing efficiency largely.

An aspect of the present invention provides a device for connecting printed circuit boards. The device comprises an insulative housing and a plurality of conductive terminals arranged in the insulative housing. The insulative housing defines a first mounting surface, a second mounting surface, and flat pickup portions respectively disposed on opposite faces of the first mounting face and the second mounting face; each terminal includes a first leg on the first mounting surface, and a second leg on the second mounting surface.

Another aspect of the present invention provides a method for connecting printed circuit boards, the method comprises: provides a device for connecting a first and a second printed circuit boards, the device having a first mounting face, a second mounting faces and comprising a plurality of conductive terminals received therein, each terminal having a first leg in the first mounting face and a second leg in the second mounting face; assembles the device onto the first printed circuit with the first mounting face facing the printed circuit board; and assembles the device onto the second printed circuit with the second mounting face facing the printed circuit board.

Yet another aspect of the present invention provides an interconnecting system, comprising: a first printed circuit board having a first surface, and a plurality of conductive first pads on the first surface along an edge thereof; a second printed circuit board having a second surface, and a plurality of conductive second pads on the second surface thereof; and a first conductive terminal block having a plurality of conductive terminals arranged therein, each the terminal having a first contact engaging portion electrically in contact with the first pad on the first surface and a second contact engaging portion electrically in contact with the second pad on the second surface.

### BRIEF DESCRIPTION OF THE DRAWINGS

Hereinafter, the above, other objects and advantages will become more apparent from the following description for embodiments of the present invention with reference to accompanying drawings.

FIG. 1 is a exploded, perspective view of a device for connecting printed circuit boards and printed circuit boards in accordance with a first embodiment of the present invention;

FIG. 2 is a perspective view of a first connecting device and a first printed circuit board of FIG. 1, wherein the first connecting device is mounted onto the first printed circuit board;

FIG. 3 is a front view of FIG. 2;

FIG. 4 is perspective view of a first connecting device, a second connecting device and a first printed circuit board of FIG. 1, wherein the first connecting device and the second connecting device are mounted onto the first printed circuit board;

FIG. 5 is a right view of FIG. 4;

FIG. 6 is an assembled, perspective view of FIG. 1;

FIG. 7 is a right view of a first terminal of the first connecting device of FIG. 2;

FIG. 8 is a right view of a first terminal of a first connecting device in accordance with a second embodiment of the present invention; and

FIG. 9 is a right view of a first connecting device of FIG. 8 into which the terminal is assembled.

### DETAILED DESCRIPTION OF THE EMBODIMENTS

Hereinafter, in order to make the above objects, features and advantages to be easily understood, embodiments of the present invention will be described in detail with reference to the accompanying drawings.

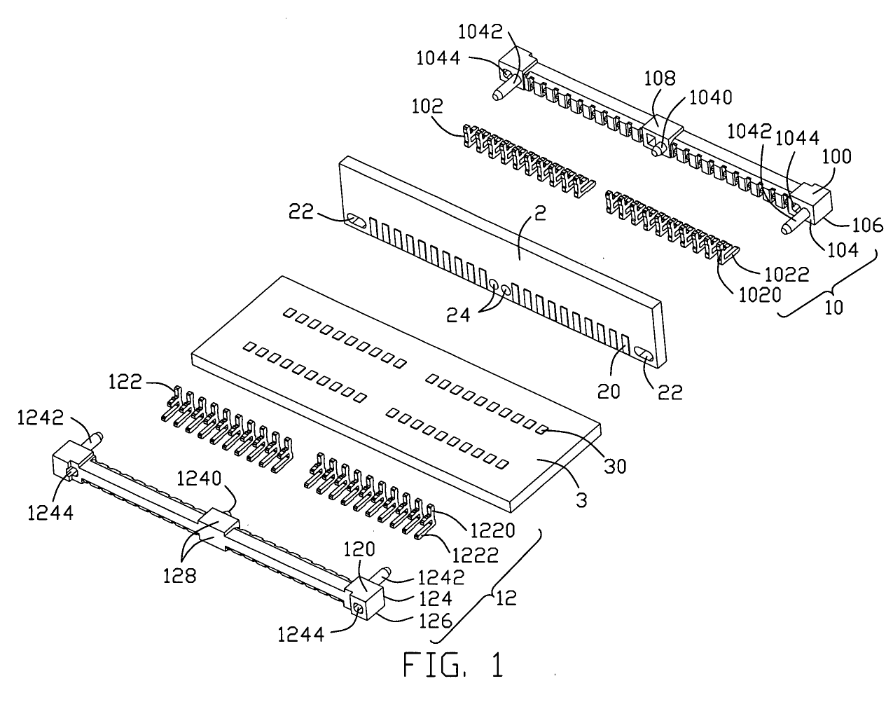

A first embodiment of the present invention is described below with reference to FIGS. 1 to 7. A device 1 for connecting printed circuit boards is configured to connect a first printed circuit board 2 with a second printed circuit board 3. The device 1 in accordance with the embodiment of the present invention comprises a first connecting device 10 and a second connecting device 12 which are mounted onto opposite sides of the first circuit board 2 side by side. Certainly, the device 1 according to the embodiment of the present invention can be only one connecting device which is mounted onto a side of the first printed circuit board 2 or can also comprise a plurality of connecting devices which are respectively mounted onto opposite two sides of the first printed circuit board 2. For example, the device 1 comprises four connecting devices. Two of the four connecting devices are fixed onto one side of the first printed circuit board 2 and the others of the four connecting devices are attached onto the other side of the first printed circuit board 2.

The first connecting device 10 and the second connecting device 12 are longitudinal, and each of the first and the second connecting devices 10, 12 has a first mounting face 104, 124 and a second mounting face 106, 126 perpendicular to the first mounting face 104, 124. Thus, the first printed circuit board 2 can be perpendicularly connected with the second printed circuit board 3. Certainly, the embodiment of the present invention is not limited to a first mounting face 104, 124 and a second mounting face 106, 126 which are perpendicular to each other. The first mounting face 104, 124 and the second mounting face 106, 126 are at an arbitrary angle, so that the first printed circuit board 2 can be connected with the second printed circuit board 3 at a slanting relation. Flat pickup portion 108, 128 are respectively disposed in opposite faces of the first mounting face 104, 124 and the second mounting face 106, 126 so as to be picked up from two directions. The flat pickup portion 108, 128 is located in a middle of the first and the second connecting devices 10, 12 for allowing a vacuum chuck of an automatic machine (not shown) to pick up the first and second connecting devices 10, 12 by vacuum sucking thereon in proper balance. The first mounting face 104 of the first connecting device 10 is opposite to the first mounting face 124 of the second connecting device 12 so that the first and the second connecting devices 10, 12 can be attached onto opposite two sides of the first printed circuit board 2. The second mounting face 106 of the first connecting device 10 and the second mounting face 106 of the second connecting device 12 are co-planar so that the first and the second connecting devices 10, 12 can be attached onto the same side of the second printed circuit board 3.

A first positioning post 1040 is disposed in a middle of the first mounting face 104 of the first connecting device 10, and a pair of second positioning posts 1042 are respectively disposed in two longitudinal ends of the first mounting face 104 of the first connecting device 10. Corresponding to the pair of second positioning posts 1042, the second connecting device 12 defines a pair of positioning holes 1244 in the first mounting face 124 thereof and the first printed circuit board 2 defines a pair of positioning holes 22 respectively for cooperating with the pair of second positioning posts 1042. A cooperating space between the second positioning post 1042 of the first connecting device 10 and the corresponding positioning holes 1244, 22 of the second connecting device 12 and the first printed circuit board 2 along a longitudinal direction of the first connecting device 10 is greater than that in other directions. Corresponding to the first positioning post 1040, the first printed circuit board 2 defines a positioning hole 24 for cooperating with the first positioning post 1040. A cooperating space between the first positioning post 1040 of the first connecting device 10 and the corresponding positioning hole 24 of the first printed circuit board 2 is the same in all directions.

A first positioning post 1240 is disposed in a middle of the first mounting face 124 of the second connecting device 12, and a pair of second positioning posts 1242 are respectively disposed in two longitudinal ends of the first mounting face 124 of the second connecting device 12. Corresponding to the pair of second positioning posts 1242, the first connecting device 10 defines a pair of positioning holes 1044 in the first mounting face 104 thereof and the first printed circuit board 2 defines a pair of positioning holes 22 respectively for cooperating with the pair of second positioning posts 1242. A cooperating space between the second positioning post 1242 of the second connecting device 12 and the corresponding positioning holes 1044, 22 of the first connecting device 10 and the first printed circuit board 2 along a longitudinal direction of the second connecting device 12 is greater than that in other directions. Corresponding to the first positioning post 1040, the first printed circuit board 2 defines a positioning hole 24 for cooperating with the first positioning post 1240. A cooperating space between the first positioning post 1240 of the second connecting device 12 and the corresponding positioning hole 24 of the first printed circuit board 2 is the same in all directions. Such design of the cooperating spaces can assure accurate orientation and can allow a greater error range, thereby reducing manufacturing difficulty, increasing quantity of final products and reducing manufacturing cost.

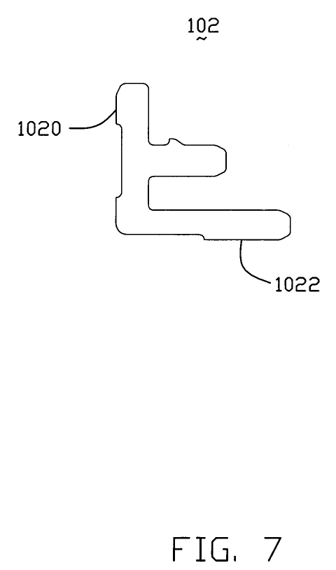

The first connecting device 10 comprises an insulative housing 100 and a plurality of conductive terminals 102 inserted in the insulative housing 100 along a direction perpendicular to the first mounting face 104, and the second connecting device 12 comprises an insulative housing 120 and a plurality of conductive terminals 122 inserted in the insulative housing 120 along a direction perpendicular to the first mounting face 124. Referring to FIG. 7, each of the first and the second conductive terminals 102, 122 comprises a first leg 1020, 1220 located in the first mounting face 104, 124 and a second leg 1022, 1222 located in the second mounting face 106, 126. The first legs 1020, 1220 are SMT (Surface Mount Technology) type and are located corresponding to solder pads 20 disposed on the first printed circuit board 2. The second legs 1022, 1222 are SMT (Surface Mount Technology) type and are located corresponding to solder pads 30 disposed on the second printed circuit board 3.

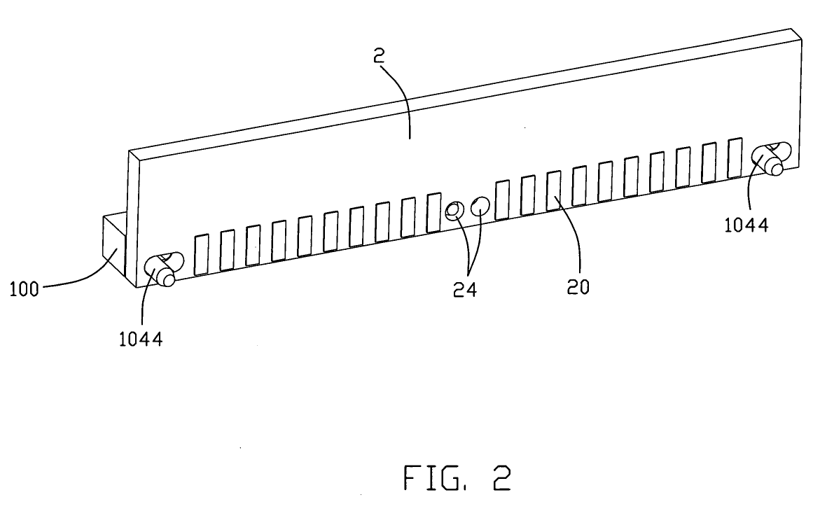

In assembly, the vacuum chuck of the automatic machine picks up the flat pickup portion 108 of the first connecting device 10 to assemble to the first printed circuit board 2, the first positioning post 1040 being received in the positioning hole 24 of the first printed circuit board 2 and the second positioning posts 1042 of the first connecting device 10 extending through the positioning hole 22 of the first printed circuit board 2. Therefore, the first connecting device 10 is positioned on the first printed circuit board 2. Then the first legs 1020 of the first connecting device 10 are soldered onto the corresponding solder pads 20 of the first printed circuit board 2. As shown in FIG. 2, the second positioning post 1042 of the first connecting device 10 has a greater length than a thickness of the first printed circuit board 2. So when the first connecting device 10 is assembled onto the first printed circuit board 2, the second positioning post 1042 of the first connecting device 10 extends partly beyond the first printed circuit board 2. Next, the vacuum chuck of the automatic machine picks up the flat pickup portion 128 of the second connecting device 12 to assemble to the first printed circuit board 2 with the first connecting device 10, the positioning holes 1244 of the second connecting device 12 receiving the second positioning posts 1042 of the first connecting device 10 protruding out of the first printed circuit board 2, the first positioning post 1240 of the second connecting device 12 being receiving in the positioning hole 24 of the first printed circuit board 2 and the second positioning posts 1242 of the second connecting device 12 being receiving in the positioning holes 1044 of the first connecting device 10 through the positioning holes 22 of the first printed circuit board 2. Therefore, the second connecting device 12 is positioned on the first printed circuit board 2 with the first connecting device 10. Then the first legs 1220 of the second connecting device 12 are soldered onto the corresponding solder pads 20 of the first printed circuit board 2.

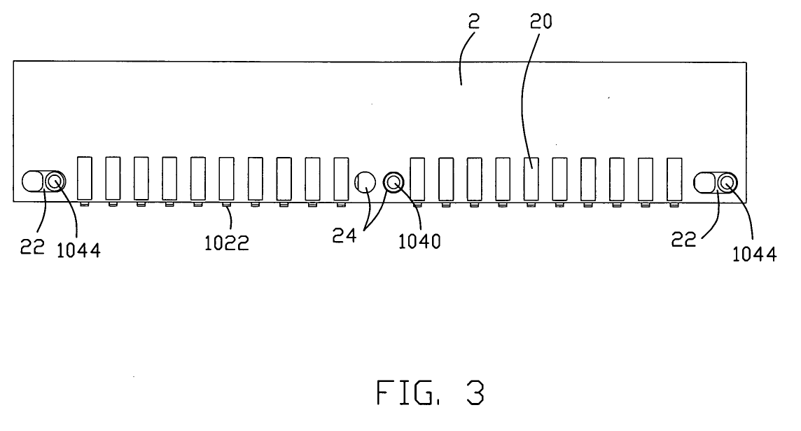

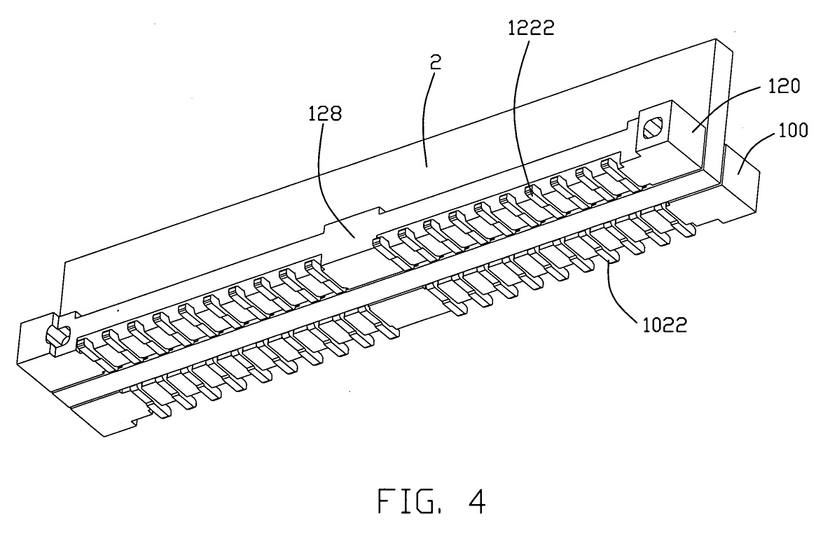

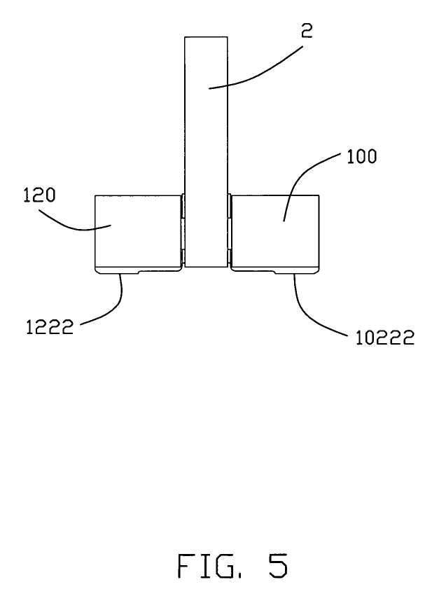

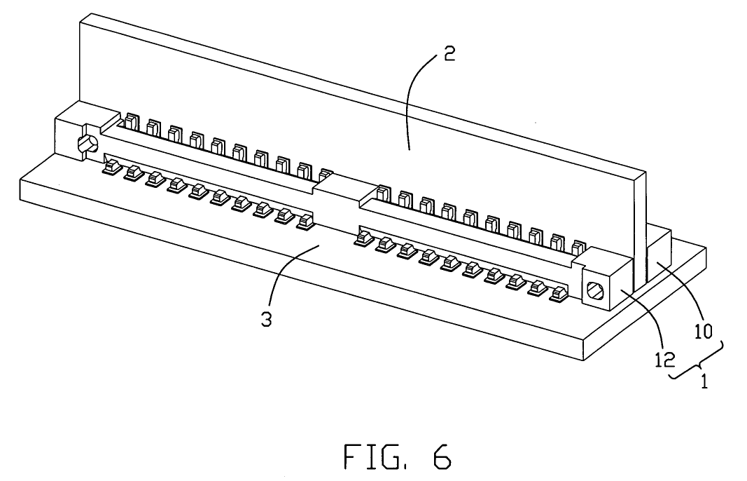

As shown in FIGS. 2 and 3, the solder pads 20 of the first printed circuit board 2 is disposed at an edge of the first printed circuit board 2. As shown in FIGS. 4 and 5, when the device 1 comprising the first connecting device 10 and the second connecting device 12 is assembled onto the first printed circuit board 2, the second legs 1022, 1222 of the second mounting faces 106, 126 of the first and the second connecting device 10, 12 protrude beyond a bottom edge of the first printed circuit board 2. The vacuum chuck of the automatic machine picks up the flat pickup portions 108, 128 of the first and the second connecting device 10, 12, and the second mounting faces 106, 126 of the first and the second connecting devices 10, 12 of the device 1 onto which the first printed circuit board 2 is mounted is attached to the second printed circuit board 3. Then the second legs 1022, 1222 of the first and the second connecting devices 10, 12 is respectively soldered onto corresponding solder pads 30 of the second printed circuit board 3. FIG. 6 illustrates that the first printed circuit board 2 and the second printed circuit board 3 are finally connected together via the first connecting device 10 and the second connecting device 12 of the device.

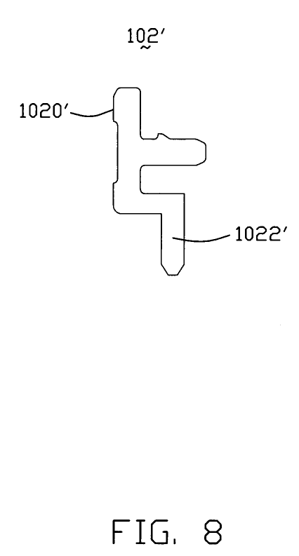

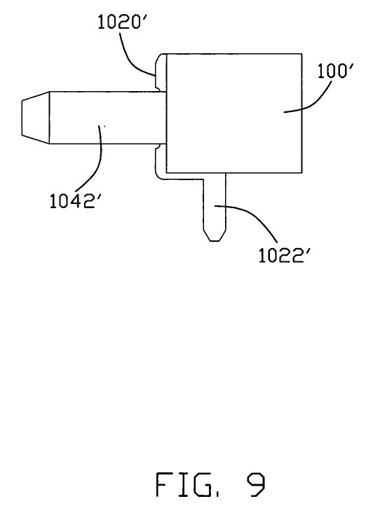

FIGS. 8 and 9 disclose the second embodiment of the present invention. With reference to FIGS. 8 and 9, different from the first embodiment, a second leg 1022′ of a first conductive terminal 102′ in accordance with the second embodiment of the present invention is T/H (Through Hole) type for providing a greater connecting intensity. Except for the second leg 1022′ of the first conductive terminal 102′, other structural features in the second embodiment are the same as that of the first embodiment. For example, a first insulative housing 100′ and a second positioning post 1042′ disposed in the first insulative housing 100′ of the second embodiment are the same as that of the first embodiment. A first leg 1020′ of the first conductive terminal 102′ in accordance with the second embodiment of the present invention is still SMT type.

The forgoing descriptions disclose the embodiments of the present invention but do not intend to limit the present invention. Additional advantages and modifications will readily occur to those skilled in the art. Therefore, the invention in its broader aspects is not limited to the specific details and representative embodiments shown and described herein. Accordingly, various modifications and variations may be made without departing from the scope of the invention as defined by the appended claims and their equivalents.

What is claimed is:

1. A device for connecting printed circuit boards comprising:
an insulative housing defining a first mounting surface, a second mounting surface, and flat pickup portions respectively disposed on opposite faces of the first mounting face and the second mounting face; and
a plurality of contact terminals arranged in the insulative housing and each including a first leg on the first mounting surface, and a second leg on the second mounting surface.

2. The device according to claim 1, wherein each the pickup portion is disposed on a balanced portion of the housing.

3. The device according to claim 2, wherein the device comprises a first connecting device and a second connecting device each having the first and the second mounting faces and the first and the second legs, the first mounting face of the first connecting device is opposite to the first mounting face of the second connecting device, and the second mounting faces of the first and the second connecting devices are co-planar.

4. The device according to claim 3, wherein the first connecting device has positioning posts on the first mounting face thereof and the second connecting device defines corresponding positioning holes for cooperating with the positioning posts.

5. The device according to claim 4, wherein a cooperating space between a positioning post at an end of the first connecting device and the corresponding positioning hole along a longitudinal direction of the first connecting device is greater than that in other directions.

6. The device according to claim 4, wherein a cooperating space between a positioning post in a middle of the first connecting device and the corresponding positioning hole is the same in all directions.

7. A method for connecting a first and a second printed circuit boards, comprising the steps of:
providing a device having a first mounting face, a second mounting faces and comprising a plurality of conductive terminals received therein, each terminal having a first leg in the first mounting face and a second leg in the second mounting face;
assembling the device onto the first printed circuit with the first mounting face facing the printed circuit board; and
assembling the device onto the second printed circuit with the second mounting face facing the printed circuit board.

8. The method according to claim 7, wherein the step of assembling the device onto the first printed circuit with the first mounting face facing the printed circuit board comprises:
picking up the device by sucking a flat pickup portion disposed on a face of the device which is opposite to the first mounting face,
putting and positioning the first mounting face of the device on the first printed circuit board, and
soldering the first legs of the terminals onto solder pads of the first printed circuit board.

9. The method according to claim 8, wherein the step of assembling the device onto the second printed circuit with the second mounting face facing the printed circuit board comprises:
picking up the device by sucking a flat pickup portion disposed on a face of the device which is opposite to the second mounting face,
putting and positioning the second mounting face of the device on the second printed circuit board, and
soldering the second legs of the terminals onto solder pads of the second printed circuit board.

10. The method according to claim 8, wherein the step of soldering the first legs onto the first printed circuit board comprises:
soldering the first legs of the terminals onto the solder pads of the first printed circuit board by SMT soldering manner.

11. The method according to claim 9, wherein the step of soldering the second legs onto the second printed circuit board comprises:
soldering the second legs of the terminals onto the solder pads of the second printed circuit board by SMT soldering manner or by through-hole soldering manner.

12. The method according to claim 7, wherein the step of providing the device comprises:
providing a first connecting device and a second connecting device, each connecting device having the first and the second mounting faces and the terminals; and
the step of assembling the device onto the first printed circuit with the first mounting face facing the printed circuit board comprises:
assembling the first mounting face of the first connecting device onto the first printed circuit with the first mounting face facing a first side of the printed circuit board, and
assembling the first mounting face of the second connecting device onto the first printed circuit with the first mounting face facing a second side of the printed circuit board, the first side opposite to the second side.

13. An interconnecting system comprising:
a first printed circuit board having a first surface, and a plurality of conductive first pads on the first surface along an edge thereof;
a second printed circuit board having a second surface, and a plurality of conductive second pads on the second surface thereof; and
a first conductive terminal block having a plurality of first conductive terminals arranged therein, each the terminal having a first contact engaging portion electrically in contact with the first pad on the first surface and a second contact engaging portion electrically in contact with the second pad on the second surface.

14. The interconnecting system according to claim 13 further comprises a second conductive terminal block, wherein:
the first printed circuit board having a third surface, and a plurality of conductive third pads on the third surface along an edge thereof;
the plurality of conductive second pads on the second surface arranged in a first line and a spaced second line;
the first contact engaging portions electrically in contact with the first pad in the first line; and
a plurality of second conductive terminals arranged in the second conductive terminal block, each the second terminal having a third contact engaging portion electrically in contact with the third pad on the third surface and a forth contact engaging portion electrically in contact with the second pad on the second surface in the second line.

15. The interconnecting system according to claim 13, wherein the first contact engaging portion and the second contact engaging portion are both soldered to the corresponding first printed circuit board and the second printed circuit board, respectively.

16. The interconnecting system according to claim 15, further including a second conductive terminal block having a plurality of second conductive terminals thereof, the first printed circuit board being fully located on the second surface of the second printed circuit board under condition of said second printed circuit board symmetrically extending on two sides of the first printed circuit board in a T like manner from a cross-sectional view, the first printed circuit board defining a third surface opposite to the first surface, said second conductive terminal defining a third contact engaging portion electrically and mechanically connected to the third surface of the printed circuit board and a fourth contact engaging portion electrically and mechanically connected to the second surface of the second printed circuit board.

17. The interconnecting system according to claim 16, wherein the first conductive terminal block and the second conductive terminal block cooperate with each other to commonly sandwich the first printed circuit board therebetween in a permanent fixed manner.

18. The interconnecting system according to claim 17, wherein each of said first and second conductive terminal blocks has a post extending through the first printed circuit board into the other in a juxtaposed manner without interlacing therebetween.

19. The interconnecting system according to claim 18. wherein a center line of the first conductive terminal block and that of the second conductive terminal block are overlapped with each other, and the post of the first conductive terminal block is located in the center line of the first conductive terminal block and the post of the second conductive terminal block is located in the center line of the second conductive terminal block and aligned with the post of the first conductive terminal block.

20. The interconnecting system according to claim 17, wherein the first printed circuit board and the second printed circuit board are essentially fully overlapped with each along a center line direction of the first conductive terminal block.
